(19) United States
(12) Patent Application Publication
(10) Pub. No.: US 2025/0046731 A1
(43) Pub. Date: Feb. 6, 2025

(54) APPARATUS WITH THINNING-BASED ALIGNMENT MARK AND METHODS OF MANUFACTURING THE SAME

(71) Applicant: Micron Technology, Inc., Boise, ID (US)

(72) Inventors: Andrew M. Bayless, Boise, ID (US); Cassie L. Bayless, Boise, ID (US)

(21) Appl. No.: 18/781,862

(22) Filed: Jul. 23, 2024

Related U.S. Application Data
(60) Provisional application No. 63/530,132, filed on Aug. 1, 2023.

(51) Int. Cl. H01L 23/544; H01L 21/304; H01L 21/67; H01L 21/78

(52) U.S. Cl. CPC H01L 23/544; H01L 21/304; H01L 21/67092; H01L 21/78; H01L 2223/54426

(57) ABSTRACT

Methods, apparatuses, and systems related to a semiconductor structure having a thinning-based alignment mark. The alignment mark may be formed by causing structural an alteration within a thickness of an initial semiconductor wafer and then thinning the initial semiconductor wafer. The thinning process may lead to a different removal rate of the altered portion and a corresponding mark at the end of the thinning process. The resulting mark may be used to identify a relative location of circuits on the thinned wafer for subsequent processing or bonding.

### CROSS-REFERENCE TO RELATED APPLICATION(S)

The present application claims priority to U.S. Provisional Patent Application No. 63/530,132, filed Aug. 1, 2023, the disclosure of which is incorporated herein by reference in its entirety.

This application contains subject matter related to provisional U.S. Patent Application No. 63/530,127, filed Aug. 1, 2023, titled “APPARATUS WITH IMPLANTED ALIGNMENT MARK AND METHODS OF MANUFACTURING THE SAME.” The related application is assigned to Micron Technology, Inc., and the subject matter thereof is incorporated herein by reference thereto.

### TECHNICAL FIELD

The disclosed embodiments relate to devices, and, in particular, to semiconductor devices with alignment marks for locating and aligning circuits and methods of manufacturing the same.

### BACKGROUND

The current trend in semiconductor fabrication is to manufacture smaller and faster devices with a higher density of components for computes, cell phones, pagers, personal digital assistants, and many other products. However, decrease in circuit size can lead to certain challenges during manufacturing processes. For example, locating circuits, such as in aligning and attaching wafers or surface mounting devices, becomes increasingly difficult as the circuits decrease in size.

### BRIEF DESCRIPTION OF THE DRAWINGS

FIG. 1A and FIG. 1B illustrate a wafer having alignment marks thereon in accordance with embodiments of the technology.

FIG. 2-FIG. 7 illustrate example phases for a manufacturing process in accordance with embodiments of the technology.

FIG. 8 is a flow diagram illustrating an example method of manufacturing an apparatus in accordance with an embodiment of the present technology.

FIG. 9 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, assemblies, or combinations thereof in accordance with the present technology can include initially forming one or more alignment marks within the silicon of the semiconductor wafer and then surfacing/exposing the buried alignment marks during a wafer thinning process. In some embodiments, the resulting alignment marks can be used for wafer-to-wafer bonding that joins at least two silicon wafers together to create a single, integrated device. The exposed alignment marks can be used to align the separate wafers, thereby accurately connecting the electrical circuits and connections between the bonded wafers.

In some embodiments, the wafer manufacturing process can include application of a stealth laser dicing to alter or intentionally damage a portion of the silicon buried under a top/front surface of the silicon wafer and under the pattern circuitry. The damaged portion of silicon would have a different refractive index compared to other portions of silicon. The stealth laser dicing technique is a highly efficient and precise process that allows the laser to focus at a targeted depth to create an imperfection or a structural alteration in the subsurface silicon. In one or more embodiments, the depth of the imperfection/alteration can correspond to a targeted thickness of the silicon wafer (e.g., ranging between 1 μm to 2 μm, with a tolerance between 0.25 μm and 0.5 μm). Additionally, stealth laser dicing can alter the silicon without producing any significant damage to the wafer overall (e.g., localized alteration/damage) since it is a low-stress process.

The laser can be applied during a front-side manufacturing process. For example, the stealth laser can be applied using one or more openings in masks used to form active circuitry components on the front side of the wafer. By performing the laser-based marking during the front-side processing (via, e.g., a shared mask/pattern), the manufacturing process can increase the accuracy in placing the marks relative to the active circuitry. In other words, the markings can consistently and accurately identify the relative locations of the active circuits.

The wafer manufacturing process can include subsequently exposing the altered/damaged portion of the silicon during a wafer thinning process. Backside portions of the wafer can be removed, such as using a dry etch process, until the remaining wafer is reduced to have the targeted thickness. During the thinning process, the altered portions of the silicon can react faster than the non-altered portions of the silicon. As a result, the wafer thinning process can remove the laser-altered portions faster than the remaining portions, thereby creating depressions in the backside surface at the laser-marked locations. For example, thinning by dry etching can be by sulfur hexafluoride (SF₆) or another similar inorganic compound. The SF₆ will weaken the bonds of the silicon oxide, reducing the thickness of the wafer. Use of the thinning process to expose the alignment marks is beneficial. For example, thinning can improve yield by reducing the amount of stress applied on the wafer during the alignment process. Reducing stress on the wafer will reduce the risk of breaking or damaging the wafer. Additionally, thinning can also improve accuracy during the alignment process. Because thinning reduces the distance between the alignment marks and the device layer, the accuracy of the alignment will improve. Moreover, thinning will also reduce the amount of reflection that occurs during the alignment process. Reflection can interfere with the alignment marks of the wafers, making it difficult to accurately align the wafers, thus thinning can alleviate this problem.

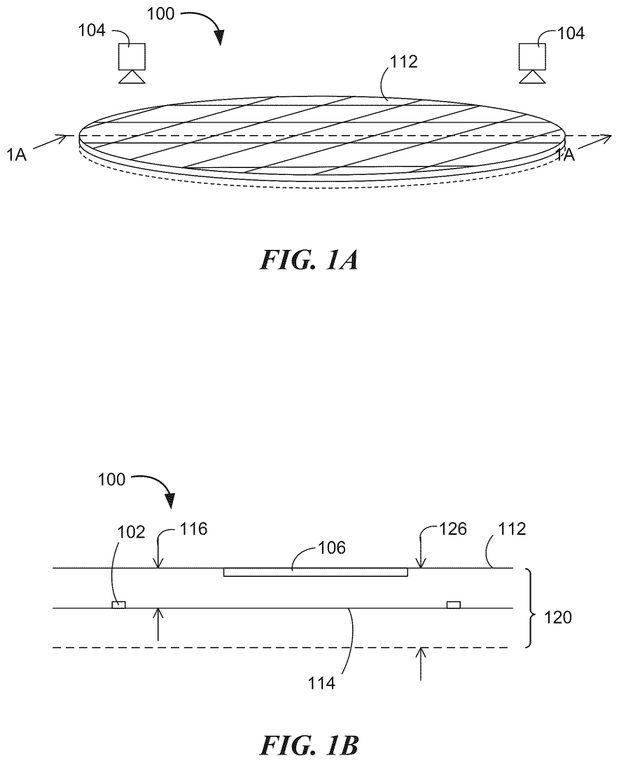

FIG. 1A and FIG. 1B illustrate a semiconductor wafer 100 having alignment marks 102 thereon in accordance with embodiments of the technology. FIG. 1A illustrates a perspective view of the wafer 100. FIG. 1B illustrates a partial cross sectional view taken along a dashed line 1A-1A of FIG. 1A. Referring to FIG. 1A and FIG. 1B together, the wafer 100 can have the alignment marks 102 formed using a marking device 104 (e.g., a laser device, such as a stealth laser).

The wafer 100 can have circuits 106 (e.g., integrated circuits) formed on an active side 112. The alignment marks 102 can be on or detectable through a passive side (e.g., a backside) opposite the active side 112. The wafer 100 can have a target thickness 116 measured between the active side 112 and the passive side 114. In some embodiments, the target thickness 116 can be 5 μm or less (e.g., 2 μm, 1 μm, or less). In other embodiments, the target thickness can be 100 nm or less (e.g., 20 nm or less).

As described in detail below, the wafer 100 can be manufactured based on forming the alignment marks 102 or corresponding structural alterations buried within an initial wafer 120 (e.g., between the active side 112 and an initial backside of the initial wafer 120). The initial wafer 120 can have an initial thickness 126 (e.g., as measured between the active side 112 and the initial backside) greater than the target thickness 116. As an illustrative example, the marking device 104 can cause the structural alterations (e.g., structural weaknesses) at a targeted depth (e.g., a depth equivalent to the target thickness 116) within the initial thickness 126. The marking device 104 can include a stealth laser configured to focus at the targeted depth below the active surface. The structural alterations can further have a predetermined shape and/or lateral dimensions.

Subsequently, the initial wafer 120 can be thinned, such as by removing a backside portion thereof using an etching process, to form the wafer 100. The etching process can cause the structural alterations to etch at a different/faster rate than other non-altered portions. Accordingly, the previously buried alignment marks 102 can surface or form as indentations in the backside/passive side 114 of the wafer 100. In some embodiments, the resulting indentations can correspond to the alignment marks 102. In other embodiments, the indentations can be filled with a contrast material (e.g. dielectric material having a unique color) to provide increased visibility/detectability. Once exposed, the alignment marks 102 can be used to accurately align the circuits 106 to circuits on another structure, such as another wafer targeted to be bonded to the wafer 100.

In some embodiments, the alignment marks 102 (e.g., results generated from the process of stealth dicing and dry etching) can be used to align at least two homogenous wafers (e.g., DRAM wafers) or heterogenous wafers (e.g., DRAM wafer and logic wafer). Further, the alignment marks 102 may be formed on the periphery of the chip, and therefore, can also be used when placing the chip onto a waver (C2W).

In some embodiments, the formation of the alignment marks 102 can occur during frontside processing of the wafer 100. In other words, the buried alignment marks 102 can be formed during, as a part of, or after forming the circuits 106. For example, the buried alignment marks 102 can be formed using a marking mask aligned with a circuit forming mask or using a designated opening on the circuit forming mask.

The buried alignment marks 102 can be formed using energy from one or more marking devices 104. In such embodiments, the marking devices 104 can be positioned above the wafer 100. A mask previously used to form the circuits 106 on the surface of the wafer 100 can further include openings for delivering the energy produced by the marking devices 104. The marking devices 104 can be configured or tuned to focus at a predetermined depth below the active side 112 of the wafer 100. Once the marking devices 104 activate, the energy can pass through the top/front surface of the wafer 100 and focus at the predetermined depth and location. The focused energy can create an imperfection/alteration at the targeted location. The resulting imperfection or altered/weakened portion is the alignment mark 102, and it can be created at or a threshold location from a target depth under the mask opening. In certain embodiments, the targeted depth of the alignment mark 102 is between 1 μm and 2 μm.

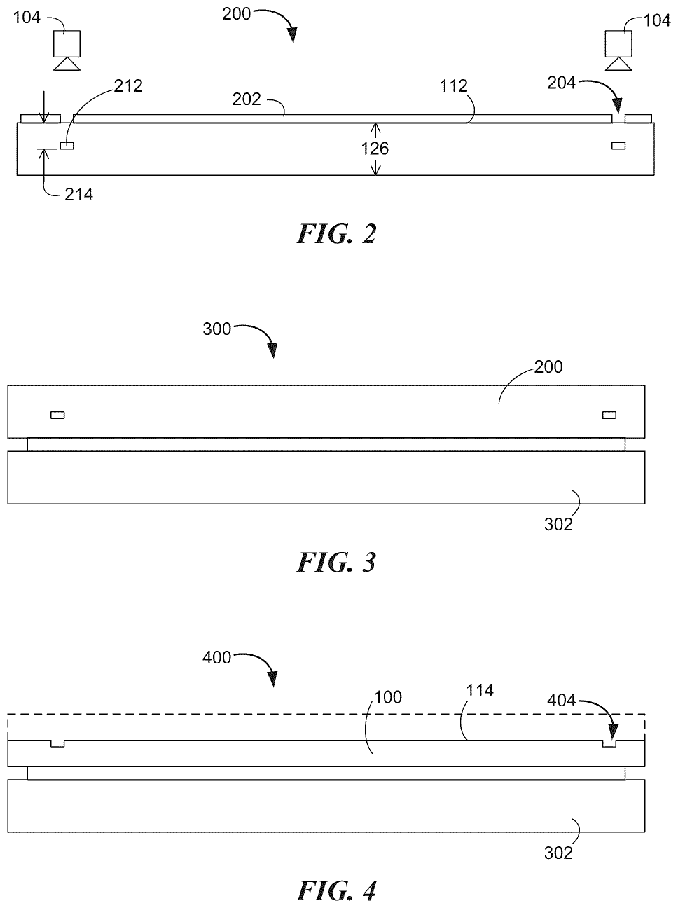

FIG. 2-FIG. 7 illustrate example phases for a manufacturing process in accordance with embodiments of the technology. FIG. 2 illustrates a cross sectional view of a semiconductor structure 200 (e.g., a wafer) in accordance with embodiments of the technology. The semiconductor structure 200 can correspond to the initial wafer 120 of FIG. 1B having the initial thickness 126 greater than the target thickness 116 of FIG. 1B.

The structure 200 can have a mask 202 over the active side 112 thereof. In some embodiments, the mask 202 can be used to form the circuits 106 of FIG. 1B or a portion thereof. In other embodiments, the mask 202 can be aligned with another mask used to form the circuits 106. Accordingly, the mask 202 can have marking openings 204 at designated/fixed locations relative to the circuits 106.

The marking devices 104 can apply stimulus or energy (e.g., focusable laser) through the marking openings 204 of the mask 202 to form buried marks 212. The marking devices 104 can form the buried marks 212 by altering the structural and/or the compositional material of the structure 200. The marking devices 104 can form the buried marks 212 below the active side 112 (e.g., top surface), such as at a marking depth 214. The marking depth 214 can correspond to the target thickness 116 (e.g., at the same depth/location as or within a threshold distance of the planned backside of the passive side 114 of FIG. 1B). In some embodiments, the marking devices 104 can be configured or tuned to focus at the marking depth 214 below the top surface. Also, the buried marks 212 can have a targeted vertical dimension that corresponds to (1) a depth for the resulting mark and/or (2) a variability or a tolerance level associated with the target thickness 116.

In addition to the targeted depth, the marking openings 204 and the corresponding buried marks 212 can be located at targeted lateral locations on the semiconductor wafer. For example, the buried marks 212 can be formed in or relative to scribe regions, active die regions, or the like for post-singulation detection.

FIG. 3 illustrates a cross sectional view of an intermediate structure 300 (e.g., a bonded structure) in accordance with embodiments of the technology. The structure 300 can have the structure 200 (e.g., the initial wafer 120 of FIG. 1B) attached or bonded to a carrier wafer 302. In some embodiments, the structure 300 can be wafer bonded to the carrier wafer 302 to enhance structural support for the initial wafer 120. In other words, the carrier wafer 302 can be electrically isolated from the circuits 106 of FIG. 1B on the initial wafer 120. Instead, the carrier wafer 302 can be bonded to the initial wafer 120 to provide additional rigidity and structural integrity for the initial wafer 120 during subsequent manufacturing processes. For example, by bonding the carrier wafer 302 to the initial wafer 120, the carrier wafer 302 can prevent structural damages to the initial wafer 120 during and after thinning.

In some embodiments, the initial wafer 120 can have a cover over the active side 112 of FIG. 1B and the circuits 106. The initial wafer 120 can be bonded to the carrier wafer 302 after forming the alignment marks 102 under the active side 112 and/or the circuits 106. In some embodiments, once the wafer 100 with the buried alignment marks 102 is bonded to the carrier wafer 202, the carrier wafer 202 can act as a support to the wafer 100 during the wafer thinning process to surface or expose the buried alignment marks.

FIG. 4 illustrates a cross sectional view of an intermediate structure 400 in accordance with embodiments of the technology. The intermediate structure 400 can represent a result of thinning the initial wafer 120 of FIG. 3 from the structure 300 of FIG. 3. The thinning process can remove a back portion of the initial wafer 120 using a dry etching process, a mechanical etching or polishing process, a chemical or wet etching process, and/or the like. The thinning process can proceed until the initial thickness 126 of FIG. 1B of the initial wafer 120 is reduced to target thickness 116. As a result, the wafer 100 can be formed or remain bonded to the carrier wafer 302, and the thinning process can establish the backside/passive side 114 of the wafer 100.

The thinning process can further form exposed marks 404, such as depressions, on the passive side 114 of the wafer 302. The exposed marks 404 can correspond to the buried marks 212 of FIG. 2. In other words, the exposed marks 404 can result from exposing and/or otherwise physically manipulating the buried marks 212. For example, the etching process can cause additional or increased removal of structurally altered portions in comparison to other portions of the initial wafer 120. The additional/increased removal can remove the buried marks 212 and form the depressions that correspond to the exposed marks 404.

The resulting depressions or the exposed marks 404 can have one or more physical traits indicative of the initial structural alteration and the subsequent accelerated removal. For example, the exposed marks 404 can have side walls that are more linear or gradual as a result of the laser-based alteration in comparison to other marks formed directly on the passive side after the thinning process, such as by etching through a mask applied to the thinned passive side. Also, the exposed marks 404 can have relatively smoother side walls or bottom walls in comparison to other marks having cracks or uneven edges indicative of being formed by applying pressure or force on the thinned passive side. Moreover, the exposed marks 404 may have side walls that have a different slope or shape compared to other marks formed by directly applying laser to the thinned passive side.

In addition to the different physical traits, the exposed marks 404 can provide greater accuracy and consistency in its relative location to the active circuit in comparison to other marks formed on the thinned backside. Conventional alignment marks are formed by a step or a process separate from the formation of the circuits, thereby introducing an additional source for error, inaccuracy, and inconsistency. In contrast, the exposed marks 404 can be formed by applying the external stimuli (e.g., the laser) during or as a part of the frontside processing to form the circuits, such as using one or more masks used for the circuit formation as a common reference. Accordingly, the exposed marks 404 can have increased accuracy and consistency in their locations relative to the integrated circuit on the wafer.

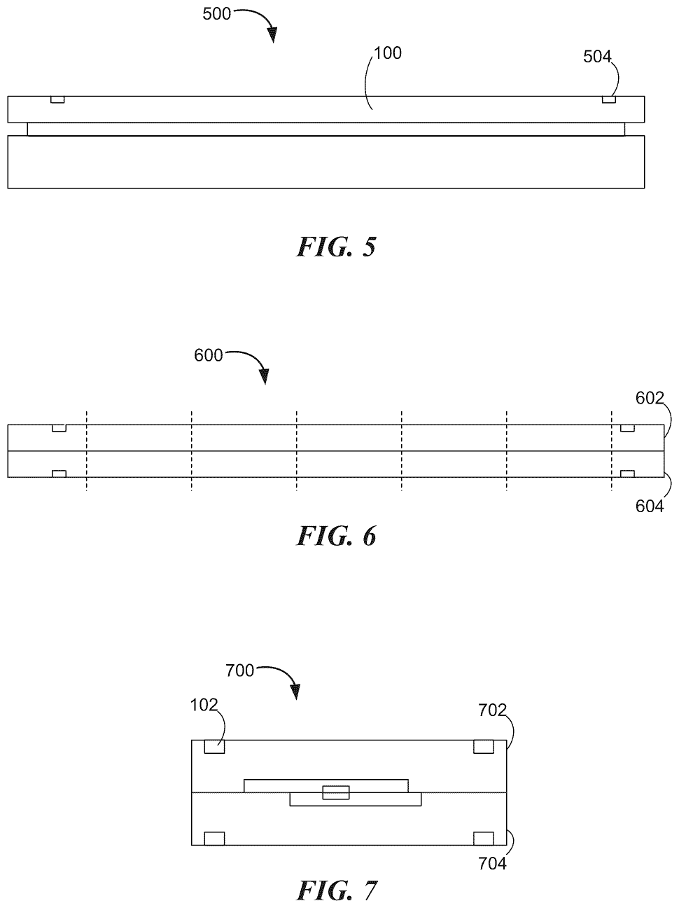

FIG. 5 illustrates a cross sectional view of an intermediate structure 500 in accordance with embodiments of the technology. The structure 500 can correspond to a result of filling the exposed marks 404 of FIG. 4 with contrast material (e.g., colored or otherwise detectable filler material) to form filled marks 504. The contrast material can be applied and then shaped (e.g., buffed via a chemical mechanical polishing (CMP) process) to form the filled marks 504. The filled marks 504 can represent the alignment marks 102 of FIG. 1B. In other embodiments, the exposed marks 404 without the filler can represent the alignment marks 102.

FIG. 6 illustrates a cross sectional view of an intermediate structure 600 in accordance with embodiments of the technology. The structure 600 can have a first semiconductor wafer 602 bonded to a second semiconductor wafer 604. The first wafer 602, the second wafer 604, or both can have alignment marks 102 of FIG. 1B. In other words, the first wafer 602, the second wafer 604, or both can result from the process described above using FIG. 2 through FIG. 5. The wafers 602 and 604 can be bonded using one or more wafer bonding techniques, such as direct bonding, hybrid bonding, oxide bonding, and the like.

In bonding the wafers, the manufacturer or a corresponding system can use the alignment marks 102 on one or both of the wafers to control a relative positioning of the wafers. In other words, the method for bonding the wafers can include aligning the wafers using the alignment marks 102 on one or both of the wafers. Accordingly, the alignment marks 102 can increase the accuracy in the relative positions of the circuits on the bonded wafers and increase the likelihood that the electrical connections are formed as intended, thereby reducing bonding failures and any associated reworks and losses. In some embodiments, the alignment marks 102 (e.g., results generated from the process of stealth dicing and dry etching) can be used to align at least two homogenous wafers (e.g., DRAM wafers) or heterogenous wafers (e.g., DRAM wafer and logic wafer). Additionally or alternatively, the alignment marks 102 may be formed on the periphery of the chip or singulation locations (e.g., at or relative to the scribe regions), and therefore, can also be used when placing the chip onto a waver (C2W).

For illustrative purposes, FIG. 6 shows the wafers bonded at the front sides. However, it is understood that the wafers can be bonded differently, such as front-to-back or back-to-back. For other relative arrangements, one or more of the circuits can have vias or other vertical connections that extend across the thickness of the wafer to connection pads/locations. The alignment marks 102 can be used to relatively locate such connection pads/locations and ensure that they contact and are connected to targeted locations on the other wafer.

In some embodiments, the bonded wafers can be configured to form memory devices. For example, one of the wafers can be an array wafer that includes data storage cells in its circuits, and another of the wafers can be a control (CMOS) wafer with circuits configured to operate or control the wafer circuits.

The dashed lines in FIG. 6 can represent a singulation or dicing process for the bonded wafers or the structure 600. FIG. 7 illustrates a cross sectional view of a semiconductor device 700 in accordance with embodiments of the technology. The device 700 can represent one of the singulated devices resulting from cutting, sawing, or otherwise dicing the structure 600 of FIG. 6. Accordingly, the device 700 can include a first die 702 bonded to a second die 704. The dies 702 and 704 can have circuits on active sides thereof.

In some embodiments, the first die 702, the second die 704, or both can have the alignment marks 102 on backsides thereof. Both the bonding and the alignment marks 102 can be remnants or byproducts of the wafer-level processing described above. Additionally or alternatively, the alignment marks 102 can be placed at designated locations about the device 700, such as to provide identifiable locations relative to one or more circuits on the device 700. The alignment marks 102 can be further utilize to position the device 700 and/or one or more portions thereof relative to other circuits, such as during a mounting process. Also, the alignment marks 102 can provide reference locations for the circuits, such as for identifying and processing manufacturing defects within the device 700.

The device 700 can include a memory device, such as a Dynamic Random-Access Memory (DRAM), a NAND Flash memory, other volatile or non-volatile memory, a combination memory, or the like. For example, one of the first dies 702 or the second die 704 can include memory array(s) configured to store and provide access to data. The other of the first dies 702 or the second die 704 can include the control circuitry (e.g., CMOS) configured to control storage of and manage the data at the memory array and/or control access to the stored data. The control circuitry can include input/output circuitry, command and/or address processing circuitry, power management circuitry, clock or coordination circuitry, and/or the like.

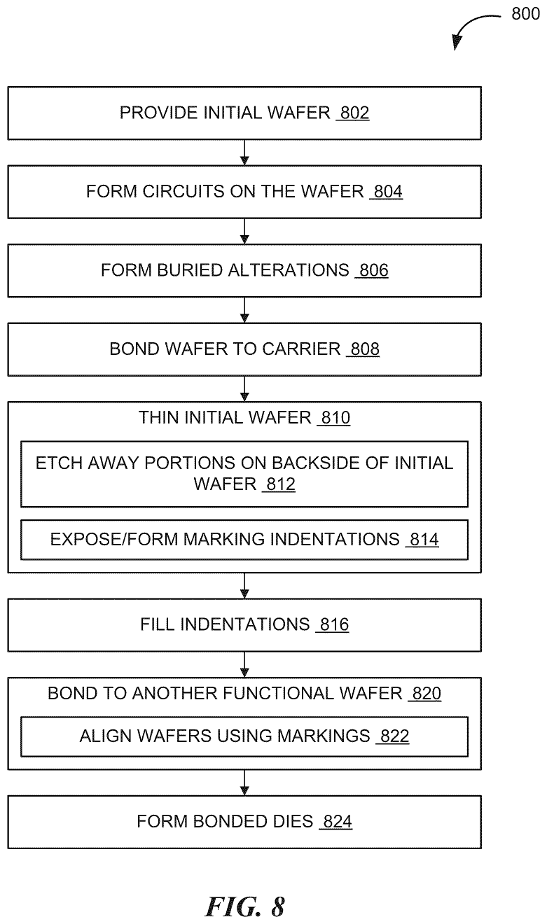

FIG. 8 is a flow diagram illustrating an example method 800 of manufacturing an apparatus in accordance with an embodiment of the present technology. The example method 800 can be for manufacturing the wafer 100 of FIG. 1B, the bonded structure 600 of FIG. 6, the device 700 of FIG. 7, or a combination thereof. For example, the method 800 can include forming and utilizing the alignment marks 102 of FIG. 1B.

The method 800 can include providing an initial semiconductor wafer (e.g., the initial wafer 120 of FIG. 1B and FIG. 2) as illustrated at block 802. The initial wafer can have the initial thickness 126 of FIG. 2.

The method 800 can include, at block 804, forming circuits (e.g., the circuits 106 of FIG. 1B) on the initial wafer. The circuits can be formed by doping, shaping, and electrically connecting various portions. Circuits, such as transistors, capacitors, diodes, and the like, can be formed using one or more masks to deposit dopants to, deposit, and/or remove various materials and portions on the active side 112 of FIG. 1B of the initial wafer.

The method 800 can include forming buried alterations (e.g., the buried marks 212 of FIG. 2) under the active/top side of the initial wafer as illustrated at block 806. For example, the method 800 can include using the marking devices 104 of FIG. 1A and FIG. 2 (e.g., stealth laser) to form the buried marks 212 at the marking depth 214 of FIG. 2. The marking devices 104 can use the mask 202 and provide the energy into the initial wafer through the marking opening 204. The marking devices 104 can be configured or tuned to focus the energy at the marking depth 214. The marking devices 104 can cause or form structural or compositional alterations at the marking depth 214 and according to the location of the marking opening 204. Accordingly, the marking devices 104 can cause or form structural or compositional alterations that correspond to the buried mark 212.

At block 808, the initial wafer can be bonded to a carrier wafer. For example, the initial wafer 120 of FIG. 3 can be bonded to the carrier wafer 302 of FIG. 3 to provide structural support for the initial wafer 120 during subsequent manufacturing processes.

At block 810, the initial wafer can be thinned. The back portions of the initial wafer can be removed or etched away as illustrated at block 812. The etching process can thin the wafer to the target thickness 116 of FIG. 1B using one or more etching processes as described above.

At block 814, the method 800 can include exposing or forming marking indentations, such as the exposed marks 404 of FIG. 4. The exposed marks 404 can result from the increased etch rate or additional removal at the buried marks 212 of FIG. 2. As described above, the structural alterations can lead to an increased etch rate/removal at the buried marks 212, thereby forming the indentations or the exposed marks 404 on the passive side 114 of the resulting wafer 100 of FIG. 4.

In some embodiments, the indentations (e.g., the exposed marks 404) can be filled as illustrated at block 816. For example, contrasting material may be used to fill the exposed marks 404, thereby forming the filled marks 504 of FIG. 5 as described above.

The thinned and marked wafer can be bonded to another functional wafer as illustrated at block 820. For example, the first wafer 602 of FIG. 6 can be bonded to the second wafer 604 of FIG. 6 as described above. Also, one or more of the wafers can be detached from corresponding carrier wafers. In bonding the wafers, the method 800 can include aligning the wafers using the alignment marks 102 (e.g., the exposed marks 404 and/or the filled marks 504) on one or more of the wafers. The alignment marks 102 can be positioned relative to other marks on another wafer and/or one or more reference locations apart from the wafers.

The method 800 can further include forming bonded dies as illustrated at block 824, such as by dicing or cutting the bonded wafers as described above. The resulting device 700 of FIG. 7 can have semiconductor devices/dies that are bonded to each other via wafer-level processing.

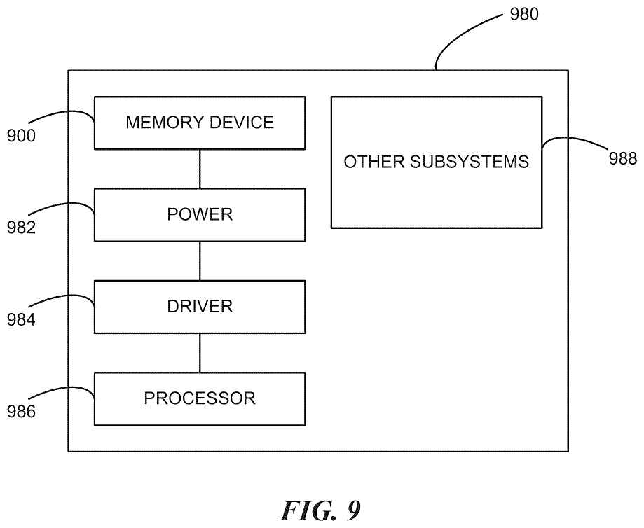

FIG. 9 is a schematic view of a system that includes an apparatus in accordance with embodiments of the present technology. Any one of the semiconductor devices described above with reference to FIGS. 1-8 can be incorporated into any of a myriad of larger and/or more complex systems, a representative example of which is system 990 shown schematically in FIG. 9. The system 990 can include a semiconductor device 900 (“device 900”) (e.g., a semiconductor device, package, and/or assembly), a power source 992, a driver 994, a processor 996, and/or other subsystems or components 998. The device 900 can include features generally similar to those devices described above. The resulting system 990 can perform any of a wide variety of functions, such as memory storage, data processing, and/or other suitable functions. Accordingly, representative systems 990 can include, without limitation, hand-held devices (e.g., mobile phones, tablets, digital readers, and digital audio players), computers, and appliances. Components of the system 990 may be housed in a single unit or distributed over multiple, interconnected units (e.g., through a communications network). The components of the system 990 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the terms “comprising,” “including,” and “having” are used throughout to mean including at least the recited feature(s) such that any greater number of the same feature and/or additional types of other features are not precluded. Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A method of manufacturing a semiconductor device, the method comprising:
providing a semiconductor wafer having an initial thickness;
forming active circuit on a front side of the semiconductor wafer;
forming an alignment mark buried within the initial thickness of the semiconductor substrate and at a depth lower than the active circuit, wherein the alignment mark corresponds to a localized structural alteration caused by one or more lasers; and
thinning the semiconductor wafer to a target thickness less than the initial thickness, wherein thinning the semiconductor wafer exposes the alignment mark for providing a reference to locate the active circuit or a portion thereof.

2. The method of claim 1, wherein forming the alignment mark includes forming the alignment mark during or as a part of frontside processing that forms the active circuit the frontside of the semiconductor wafer.

3. The method of claim 2, wherein forming the alignment mark includes:
updating an existing mask to include openings for receiving stimuli from the one or more lasers, wherein the exiting mask is used to form the active circuit or a portion thereof; and
introducing the stimuli from the one or more lasers through the updated openings in the existing mask.

4. The method of claim 1, wherein the alignment mark is created at or a threshold distance from a target depth that is equal to the target thickness, wherein the depth is measured from an active side along a vertical direction.

5. The method of claim 4, wherein the depth for the alignment mark is 2 μm or less from the active side surface.

6. The method of claim 4, wherein forming the alignment mark includes setting a focus for the one or more lasers as the target depth, wherein the focus causes the alteration to form at the target depth without altering the active side.

7. The method of claim 1, further comprising bonding the semiconductor wafer to a carrier wafer after forming the alignment mark for support during at least the thinning process.

8. The method of claim 1, wherein thinning of the semiconductor wafer to the target thickness forms (1) a backside surface and (2) the alignment mark that correspond to depressions in the backside surface, wherein the depressions are caused by an accelerated removal of the alteration in comparison to other portions of the semiconductor wafer.

9. The method of claim 8, wherein thinning of the semiconductor wafer includes:
chemical mechanical polishing,
wet etching,
dry chemical etching, and/or
any combination thereof.

10. The method of claim 1, further comprising filling the exposed alignment mark with a contrasting material, wherein the exposed alignment mark is recessed from a backside surface of the thinned semiconductor wafer.

11. The method of claim 1, further comprising:
aligning the semiconductor wafer to a second wafer or a common reference location using the alignment mark, wherein the semiconductor wafer is a first wafer;
bonding the first and second wafers together for providing vertically arranged circuits that extend across thicknesses of the bonded first and second wafers; and
dicing the bonded first and second wafers to form a semiconductor device, wherein the semiconductor device includes the alignment mark.

12. The method of claim 11, wherein:
the alignment mark is a first mark;
the second wafer includes a second mark; and
aligning the semiconductor wafer includes aligning the first and second marks.

13. The method of claim 1, wherein the formed alignment mark has a vertical dimension associated with a tolerance level for the target thickness, a depth for the exposed alignment mark, or a combination thereof.

14. A semiconductor wafer, comprising:
an active side opposite a passive side across an initial thickness;
active circuit on the active side or closer to the active side than the passive side; and
a structural alteration at a target depth between the active and passive sides,
wherein the structural alteration corresponds to a portion of the wafer weakened by externally applied energy, and
wherein the structural alteration is localized to a vertical dimension, a set of lateral dimensions, a shape, or a combination thereof associated with bonding accuracy for the active circuit.

15. The semiconductor wafer of claim 14, wherein the active circuit includes (1) an array of memory cells or (2) a control circuit configured to store data into and access data from the array of memory cells.

16. A semiconductor structure, comprising:
an active side opposite a passive side across a target thickness;
active circuit on the active side or closer to the active side than the passive side; and
a depression on the passive side,
wherein the depression corresponds to an alignment mark that indicates a relative location of the active circuit for aligning and connecting the active circuit to a different circuit, and
wherein the depression is defined by edges having one or more slopes and/or shapes characteristic of resulting from accelerated removal of altered structural portions during an etching process.

17. The semiconductor structure of claim 16, further comprising:
a filler inside the depression and coplanar with surrounding portions of the passive side, wherein the filler includes one or more detectable traits that distinguish from the surrounding portions of the passive side.

18. The semiconductor structure of claim 16, wherein:
the semiconductor structure comprises a semiconductor wafer; and
wherein the depression corresponds to the alignment mark used to align and bond the semiconductor wafer to another wafer.

19. The semiconductor structure of claim 16, wherein:
the semiconductor structure comprises a bonded set of first and second semiconductor wafers;
the active and passive sides define the first semiconductor wafer;
the depression is on the first semiconductor wafer; and
the second semiconductor wafer includes a local marker aligned with the depression.

20. The semiconductor structure of claim 16, wherein:
the semiconductor structure comprises a bonded set of first and second semiconductor dies;
the active and passive sides define the first semiconductor die; and
the depression is on the first semiconductor dies.
